(19) United States
(12) Patent Application Publication
(10) Pub. No.: US 2025/0016957 A1
(43) Pub. Date: Jan. 9, 2025

(54) COOLING FLUID CIRCULATION MODULE AND ELECTRONIC DEVICE COMPRISING THE SAME

(71) Applicants: SAMSUNG ELECTRONICS CO., LTD., Suwon-si (KR); CHUNG ANG University Industry Academic Cooperation Foundation, Seoul (KR)

(72) Inventors: Daehyuk SON, Suwon-si (KR); Sungchan Kang, Suwon-si (KR); Seongwoo Hong, Suwon-si (KR); Daeyoung Kong, Seoul (KR); Kiwan Kim, Seoul (KR); Hyoungsoon Lee, Seoul (KR)

(73) Assignee: SAMSUNG ELECTRONICS CO., LTD., Suwon-si (KR)

(21) Appl. No.: 18/797,053

(22) Filed: Aug. 7, 2024

(30) Foreign Application Priority Data
Jul. 8, 2023 (KR) 10-2023-0103127

(51) Int. Cl. H05K 7/20; H01L 23/473

(52) U.S. Cl. CPC H05K 7/20272; H01L 23/473

(57) ABSTRACT

A cooling fluid circulation module includes: a first surface having a planar form and contacting a heating portion; a second surface opposite to the first surface and having a planar form, the second surface being spaced apart from the first surface; a first cooling channel extending between the first surface and the second surface in a first direction; a cooling fluid provided in the first cooling channel; and a plurality of first protrusions arranged along a plane on the second surface on which the first cooling channel extends, wherein each of the plurality of first protrusions may include a first surface inclined from the second surface by a first angle and a second surface inclined from the second surface by a second angle that is different than the first angle.

### CROSS-REFERENCE TO RELATED APPLICATION

This application is based on and claims priority under 35 U.S.C. § 119 to Korean Patent Application No. 10-2023-0103127, filed on Aug. 7, 2023, in the Korean Intellectual Property Office, the disclosure of which is incorporated by reference herein in its entirety.

### BACKGROUND

### 1. Field

The disclosure relates to a cooling fluid circulation module and an electronic device including the same.

### 2. Description of Related Art

Air cooling devices have been used to remove heat generated from electronic devices. However, liquid cooling devices are used to deal with the increased heat generation in electronic devices due to high power density. Moreover, there has been a growing interest in next-generation cooling methods with high efficiency, such as liquid cooling devices to reduce power consumption in data centers. Liquid cooling methods may be divided into a single-phase liquid cooling method, utilizing the sensible heat of a coolant, and a two-phase liquid cooling method, involving latent heat through a phase change in a coolant. The two-phase liquid cooling method may be able to deal with a wider range of a heat generation amount than the single-phase liquid cooling method.

### SUMMARY

Provided are a cooling fluid circulation module employing a two-phase cooling structure and an electronic device including the cooling fluid circulation apparatus.

Further, provided are a cooling fluid circulation module that handles a decrease in the cooling efficiency due to vapor generation, and an electronic device including the cooling fluid circulation apparatus.

Further still, provided are a cooling fluid circulation module that enhances both energy and cooling efficiency by moving coolant and generated vapor in one direction without the need for an additional pumping device, along with an electronic device including the cooling fluid circulation apparatus.

Additional aspects will be set forth in part in the description which follows and, in part, will be apparent from the description, or may be learned by practice of the presented embodiments of the disclosure.

According to an aspect of an example embodiment, a cooling fluid circulation module includes: a first surface having a planar form and contacting a heating portion; a second surface opposite to the first surface and having a planar form, the second surface being spaced apart from the first surface; a first cooling channel extending between the first surface and the second surface in a first direction; a cooling fluid provided in the first cooling channel; and a plurality of first protrusions arranged along a plane on the second surface on which the first cooling channel extends, wherein each of the plurality of first protrusions may include a first surface inclined from the second surface by a first angle and a second surface inclined from the second surface by a second angle that is different than the first angle.

A difference between the first angle and the second angle of each of the plurality of first protrusions may increase sequentially in the first direction, and a height of each of the plurality of first protrusions may decrease sequentially in the first direction.

The cooling fluid circulation module may further include a plurality of second protrusions arranged along a plane on the first surface on which the first cooling channel extends, and each of the plurality of second protrusions may include a third surface inclined from the first surface by a third angle and a fourth surface inclined from the first surface by a fourth angle that is different than the third angle.

A difference between the third angle and the fourth angle of each of the plurality of second protrusions may increase sequentially in the first direction, and a height of each of the plurality of second protrusions may decrease sequentially in the first direction.

The cooling fluid may include at least one of a coolant HFE-7100, a coolant FC-72, a coolant PF-5060, a coolant R-245fa, a coolant R-1233zd, diethyl ether, ethanol, acetone, or distilled water.

The second surface may contact a cooling portion for cooling the cooling fluid, the cooling fluid circulation module may further include: a second cooling channel extending between the second surface and the first surface in a second direction opposite to the first direction; and a plurality of third protrusions arranged along a plane on the second surface on which the second cooling channel extends, and each of the plurality of third protrusions may include a fifth surface inclined from the second surface by a fifth angle and a sixth surface inclined by the second surface at a sixth angle that is different than the fifth angle.

A difference between the fifth angle and the sixth angle of each of the plurality of third protrusions may decrease sequentially in the second direction, and a height of each of the plurality of third protrusions may increase sequentially in the second direction.

The cooling fluid circulation module may further include a plurality of fourth protrusions arranged along a plane on the first surface on which the second cooling channel is arranged, and each of the plurality of fourth protrusions may include a seventh surface inclined from the first surface by a seventh angle and an eighth surface inclined from the first surface by an eighth angle that is different than the seventh angle.

A difference between the seventh angle and the eighth angle of each of the plurality of fourth protrusions may decrease sequentially in the second direction, and a height of each of the plurality of fourth protrusions may increase sequentially in the second direction.

The cooling fluid circulation module may further include: a middle partition wall between the second surface and the first surface, and blocking the first cooling channel and the second cooling channel from each other; a third cooling channel connecting the first cooling channel to the second cooling channel, and extending in a third direction perpendicular to the first direction; and a fourth cooling channel connecting the first cooling channel to the second cooling channel, and extending in a fourth direction opposite to the third direction.

Each of the second surface, the first surface, and the plurality of first protrusions may include at least one of aluminum, copper, or silicon.

According to an aspect of an example embodiment, a cooling fluid circulation module includes: a first surface having a planar form and contacting a heating portion; a second surface having a plane form and opposite to the first surface, the second surface being spaced apart from the first surface; a first cooling channel between the first surface and the second surface; a cooling fluid provided in the first cooling channel and moving in a first direction; and a plurality of first patterns arranged along a plane on the second surface and including a hydrophobic material, wherein each of the plurality of first patterns has a first width in a second direction that is opposite to the first direction, the first width gradually decreasing in a third direction perpendicular to the first direction.

The cooling fluid circulation module may further include a plurality of second patterns arranged along a plane on the first surface and including a hydrophobic material, and each of the plurality of second patterns has a second width in the second direction, the second width gradually decreasing in the third direction.

The hydrophobic material may include at least one of perfluoroalkoxy alkane (PFA), polytetrafluoroethylene (PTFE), or polyimide (PI).

Each of the second surface and the first surface may include at least one of aluminum, copper, or silicon.

The cooling fluid may include at least one of a coolant HFE-7100, a coolant FC-72, a coolant PF-5060, a coolant R-245fa, a coolant R-1233zd, diethyl ether, ethanol, acetone, or distilled water.

The second surface may contact a cooling portion, the cooling fluid circulation module may further include: a second cooling channel between the second surface and the first surface, wherein the cooling fluid moves in the second cooling channel in the second direction; and a plurality of third patterns arranged along a plane on the second surface on which the second cooling channel extends and including a hydrophobic material, and each of the plurality of third patterns may have a third width in the first direction, the third width gradually decreasing in the third direction.

The cooling fluid circulation module may further include a plurality of fourth patterns arranged along a plane on the first surface on which the second cooling channel extends, each of the plurality of fourth patterns may have a fourth width in the first direction, the fourth width gradually decreasing in the third direction.

The cooling fluid circulation module may further include: a middle partition wall between the second surface and the first surface, and blocking the first cooling channel and the second cooling channel from each other; a third cooling channel connecting the first cooling channel to the second cooling channel, and extending in the third direction perpendicular to the first direction; and a fourth cooling channel connecting the first cooling channel to the second cooling channel, and extending in a fourth direction opposite to the third direction.

According to an aspect of an example embodiment, an electronic device includes: a heating portion; a cooling portion; a cooling fluid circulation module including: a first surface having a planar form and contacting the heating portion; a second surface opposite to the first surface and having a planar form, the second surface being spaced apart from the first surface; a first cooling channel extending between the first surface and the second surface in a first direction; a cooling fluid provided in the first cooling channel; and a plurality of first protrusions arranged along a plane on the second surface on which the first cooling channel extends, wherein each of the plurality of first protrusions may include a first surface inclined from the second surface by a first angle and a second surface inclined from the second surface by a second angle that is different than the first angle.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an electronic device, according to an embodiment;

FIG. 2 is a schematic plan view of a cooling fluid circulation apparatus, according to an embodiment;

FIG. 3 is a schematic perspective view of an upper surface of a cooling fluid circulation apparatus, according to an embodiment;

FIG. 4 is a schematic diagram of a plurality of first protrusions, according to an embodiment;

FIG. 5 is a schematic diagram of a plurality of first protrusions, a plurality of second protrusions, and a second cooling channel, according to an embodiment;

FIG. 6 is a schematic cross-sectional view of an electronic device, according to an embodiment;

FIG. 7 is a schematic diagram of a plurality of third protrusions, a plurality of fourth protrusions, and a second cooling channel, according to an embodiment;

FIG. 8 is a schematic plan view of a cooling fluid circulation apparatus, according to an embodiment;

FIG. 9 is a schematic perspective view of a lower surface of a cooling fluid circulation apparatus, according to an embodiment;

FIG. 10 is a schematic diagram of a plurality of second patterns, according to an embodiment;

FIG. 11 is a schematic diagram of a plurality of second patterns, according to an embodiment;

FIGS. 12A to 12C are schematic diagrams illustrating a flow of a cooling fluid along a plurality of second patterns, according to an embodiment; and

FIG. 13 is a schematic diagram of an electronic device, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. In the drawings, like reference numerals in the drawings denote like elements, and sizes of components in the drawings may be exaggerated for clarity and convenience of explanation. Embodiments described below are provided only as an example, and thus can be embodied in various forms. It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described. The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations. Moreover, the terms “part,” “module,” etc. refer to a unit processing at least one function or operation, and may be implemented by a hardware, a software, or a combination thereof. The connecting lines, or connectors shown in the various figures presented are intended to represent exemplary functional relationships and/or physical or logical couplings between the various elements, and thus it should be noted that many alternative or additional functional relationships, physical connections or logical connections may be present in a practical device. The use of any and all examples, or exemplary language provided herein, is intended merely to better illuminate technical ideas and does not pose a limitation on the scope of embodiments unless otherwise claimed.

A first direction (+X) may refer to a direction from among directions parallel with a surface of an electronic device in contact with a cooling fluid circulation module. A second direction (−X) may refer to a direction which is different from the first direction (+X), from among directions parallel with a surface of an electronic device in contact with a cooling fluid circulation module. A third direction (+Y) may refer to a direction which is perpendicular to the first direction (+X), from among directions parallel with a surface of an electronic device in contact with a cooling fluid circulation module. A fourth direction (—Y) may refer to a direction which is different from the third direction (+Y), from among directions parallel with a surface of an electronic device in contact with a cooling fluid circulation module.

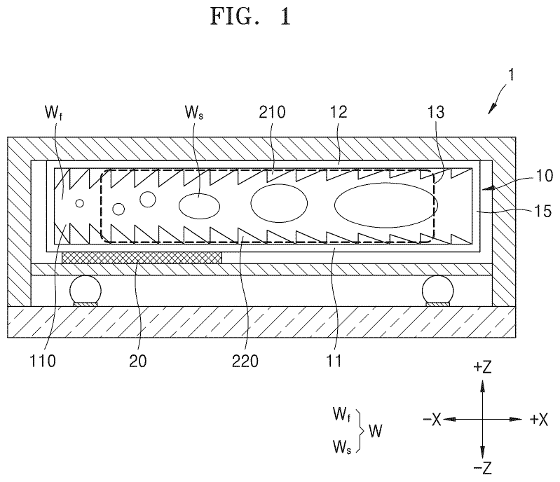

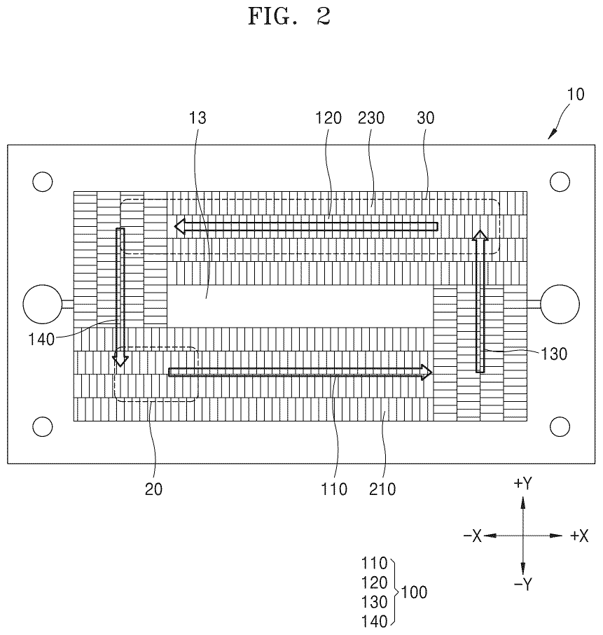

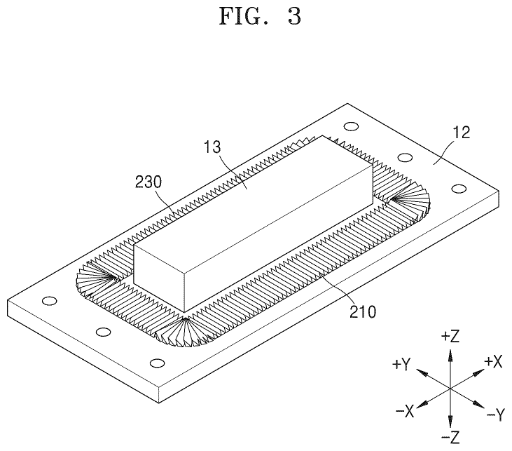

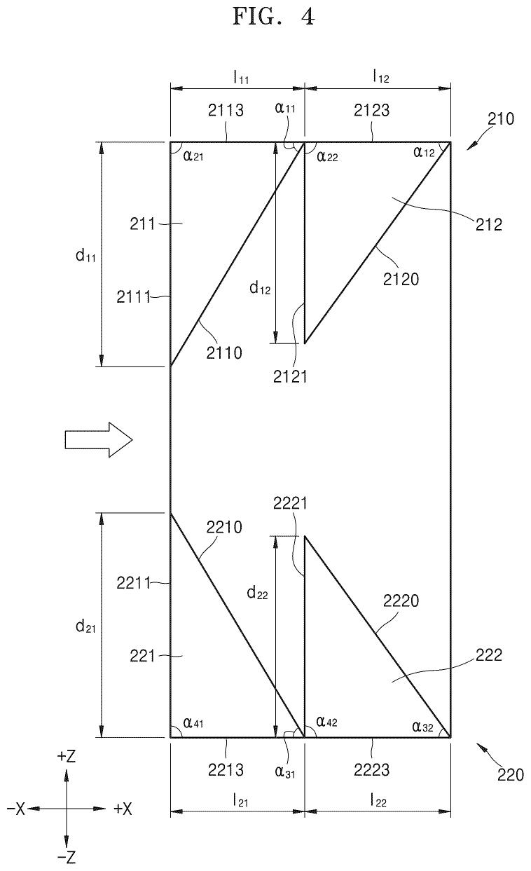

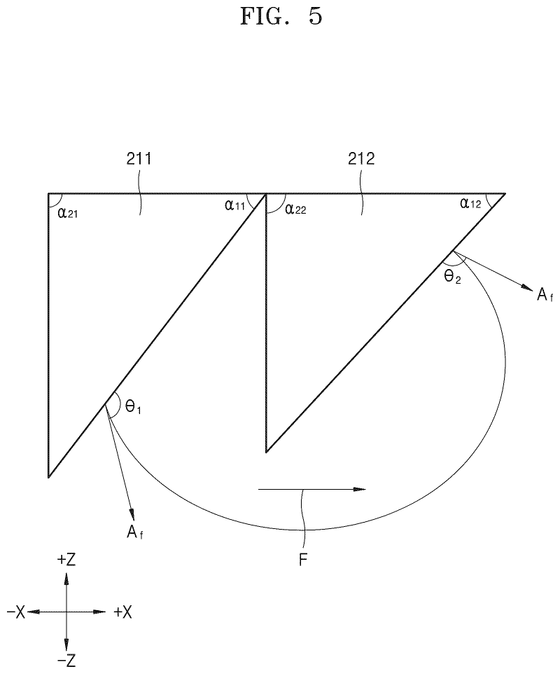

FIG. 1 is a schematic cross-sectional view of an electronic device according to an embodiment. FIG. 2 is a schematic plan view of a cooling fluid circulation module or apparatus according to an embodiment. FIG. 3 is a schematic perspective view of an upper surface of a cooling fluid circulation module according to an embodiment. FIG. 4 is a schematic diagram of a plurality of first protrusions according to an embodiment. FIG. 5 is a schematic diagram of a plurality of first protrusions, a plurality of second protrusions, and a second cooling channel according to an embodiment.

Referring to FIGS. 1 to 3, an electronic device 1 according to an embodiment may include a cooling fluid circulation module 10, a heating portion 20, and a cooling portion 30. The electronic device 1 according to an embodiment may use an efficient cooling system to solve the cooling problem. The cooling problem has been a factor limiting the performance of electronic devices.

For example, when the electronic device 1 is a semiconductor device to which high performance computing (HPC) and a stacked 3D semiconductor integrated circuit are applied, a semiconductor chip (integrated circuit die) may be included as the heating portion 20. According to the increased power density and high-density integration, the heat generation amount may increase. Accordingly, a cooling system capable of dealing with the increased heat generation amount may be required. To meet such a demand, a two-phase cooling system using evaporative latent heat may be applied to an integrated circuit device. The two-phase cooling system may include immersion cooling, spray cooling, jet impingement cooling.

The immersion cooling is a method of cooling the heating portion 20, a cooling target, by immersing the heating portion 20 in a bath with a liquid coolant. However, as the entire heating portion 20 may need to be immersed in a liquid coolant, only a dielectric coolant may be used. Accordingly, this method may incur high management expenses and have issues regarding eco-friendliness. In addition, when generated vapor adheres to a heating surface, the vapor may interrupt heat transfer from the heating surface to a coolant, which leads to decreased cooling efficiency. This situation may trigger an early critical heat flux(CHF), which represents the upper thermal limit of cooling. Increasing the CHF may be necessary to accommodate higher heat flux for effective cooling.

The spray cooling is a method of atomizing a liquid coolant and spraying the same on a heating surface and has high cooling efficiency in consideration of an amount of the used liquid coolant. However, a spray cooling device may need a pumping device capable of operating at high pressure, and a spray nozzle requires constant maintenance. The spray cooling also involves the issue of decreased cooling efficiency due to the film boiling phenomenon.

The jet impingement cooling is a method of injecting a liquid coolant on a heating surface at a high speed. Although this method has high cooling efficiency like the spray cooling method, multiple injectors may be needed to evenly cool a heating surface. Moreover, even when multiple injectors are used, there may still be a blind spot which jets of the coolant may not reach. In addition, the jet impingement cooling also contains the issue of decreased cooling efficiency due to the film boiling phenomenon.

The electronic device 1 according to an embodiment may include a two-phase cooling system. For example, the electronic device 1 may include the cooling fluid circulation module 10 configured to receive heat by making contact with the heating portion 20, e.g., a semiconductor chip and release heat by making contact with the cooling portion 30.

The cooling fluid circulation module 10 according to an embodiment may include a lower surface 11 of a plane form and being in contact with the heating portion 20, an upper surface 12 of a plane form and being in contact with the cooling portion 30, and a middle partition wall 13 arranged between the lower surface 11 and the upper surface 12. Although it is described above that the lower surface 11 is in contact with the heating portion 20, and the upper surface 12 is in contact with the cooling portion 30, the disclosure is not limited thereto, and the lower surface 11 may be in contact with the cooling portion 30, and the upper surface 12 may be in contact with the heating portion 20.

The upper surface 12 according to an embodiment may be spaced a certain apart from the lower surface 11 at a certain distance in an opposite direction (+Z) of the gravity direction (—Z). In this regard, a lateral portion 15 may be arranged between the lower surface 11 and the upper surface 12 to surround the lower surface 11 and the upper surface 12. Accordingly, a closed space disconnected from the outside may be formed by the lower surface 11, the upper surface 12, and the lateral portion 15. A cooling fluid W may be disposed in the closed space formed by the lower surface 11, the upper surface 12, and the lateral portion 15.

The cooling fluid circulation module 10 according to an embodiment may further include a cooling channel 100, in which the cooling fluid W may move, between the lower surface 11 and the upper surface 12. For example, the middle partition wall 13 may be arranged between the upper surface 12 and the lower surface 11 extending along a plane (XY plane). As the middle partition wall 13 extends in the opposite direction (+Z) of the gravity direction to the upper surface 12 from the lower surface 11, the middle partition wall 13 may block an area between the lower surface 11 and the upper surface 12. Accordingly, the cooling channel 100 in which the cooling fluid W may move may be formed between the lower surface 11 and the upper surface 12.

According to an embodiment, a first cooling channel 110 may extend in a first direction (+X) between the lower surface 11 and the upper surface 12. For example, the heating portion 20 may be arranged on the lower surface 11 on which the first cooling channel 110 is arranged and transfer heat to the cooling fluid W disposed in the first cooling channel 110.

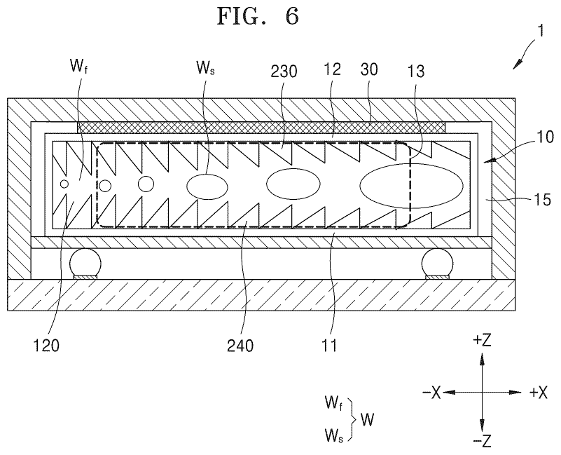

A second cooling channel 120 may extend in a second direction (−X) between the lower surface 11 and the upper surface 12. The second cooling channel 120 according to an embodiment may be arranged to face the first cooling channel 110 with the middle partition wall 13 arranged therebetween. Accordingly, the first cooling channel 110 and the second cooling channel 120 may be blocked from each other by the middle partition wall 13. For example, the cooling portion 30 (see FIG. 6) may be arranged on the upper surface 12 on which the second cooling channel 120 is arranged. The cooling portion 30 may receive heat from the cooling fluid W disposed in the second cooling channel 120.

A third cooling channel 130 may connect the first cooling channel 110 to the second cooling channel 120 and extend in a third direction (+Y) perpendicular to the first direction (+X). A fourth cooling channel 140 may connect the first cooling channel 110 to the second cooling channel 120 and extend in a fourth direction (—Y) opposite to the third direction (+Y). Accordingly, one cooling channel 100 may be formed by the first cooling channel 110, the second cooling channel 120, the third cooling channel 130, and the fourth cooling channel 140, which are connected to each other.

The cooling fluid W according to an embodiment may move along the cooling channel 100 via the first cooling channel 110, the third cooling channel 130, the second cooling channel 120, and the fourth cooling channel 140 and release heat received from the heating portion 20 to the cooling portion 30. For example, in the cooling fluid circulation module 10 including a two-phase cooling system, the cooling fluid W may receive heat from the heating portion 20 and release the heat to the cooling portion 30 through convective heat transfer and latent heat transport.

The cooling fluid W may be determined according to an operation temperature of the heating portion 20. For example, the cooling fluid W may include at least one of a coolant HFE-7100, a coolant FC-72, a coolant PF-5060, a coolant HFE-7100, a coolant FC-72, a coolant PF-5060, a coolant R-245fa, a coolant R-1233zd, diethyl ether, ethanol, acetone, and distilled water. A range of operation temperature of the heating portion 20 in which vapor pressure may be generated under atmospheric pressure may be 61 degrees for the coolant HFE-7100, 56 degrees for the coolant PF-5060, 15 degrees for the coolant R-245fa, 19 degrees for the coolant R-1233zd, 34.6 degrees for diethyl ether, 56 degrees for acetone, 78.37 degrees for ethanol, and 100 degrees for distilled water. However, the disclosure is not limited thereto, and the cooling fluid W out of the operation temperature range of the heating portion 20 may also be used.

According to an embodiment, a liquid cooling fluid Wₜ may be disposed in the first cooling channel 110. In the first cooling channel 110, the liquid cooling fluid Wₜ may absorb heat from a heat transfer surface adjacent to the heating portion 20 and be vaporized. Vapor Wₛ may be formed by the heat absorption and vaporization of the liquid cooling fluid Wₜ. When the vapor Wₛ adheres to the lower surface 11 or the upper surface 12 and is stagnant, due to the vapor film and stagnant coolant, the cooling efficiency may decrease, and a hot spot may be generated.

According to an embodiment, to move the stagnant vapor Wₛ in the first cooling channel 110 to the second cooling channel 120 where the cooling portion 30 is arranged, a plurality of first protrusions 210 may be arranged along a plane (XY) on the upper surface 12 on which the first cooling channel 110 is arranged, and a plurality of second protrusions 220 may be arranged along a plane (XY) on the lower surface 11 on which the first cooling channel 110 is arranged.

Each of the plurality of first protrusions 210 according to an embodiment may have an asymmetrical triangular cross-section taken along a plane (XZ plane) perpendicular to the upper surface 12. For example, as illustrated in FIG. 4, the plurality of first protrusions 210 may include a 1-1 protrusion 211 and a 1-2 protrusion 212 aligned in the first direction (+X). Although FIG. 4 illustrates only two protrusions, the disclosure is not limited thereto. The plurality of first protrusions 210 may include, according to the length of the first cooling channel 110, two or more protrusions aligned in order in the first direction (+X). Hereinafter, each of the plurality of first protrusions 210 is described focusing on the 1-1 protrusion 211 and the 1-2 protrusion 212 for convenience sake.

The 1-1 protrusion 211 may include a 1-1 surface 2110 inclined from the upper surface 12 by a 1-1 angle α₁₁ and a 1-2 surface 2111 inclined from the upper surface 12 by a 1-2 angle α₂₁ different from the 1-1 angle α₁₁. The 1-1 protrusion 211 may include a bottom surface 2113 in contact with the upper surface 12 and having a certain length l₁₁ and may have a height d₁₁ perpendicular to the bottom surface 2113. The 1-2 protrusion 212 may include a 1-1 surface 2120 inclined from the upper surface 12 by a 1-1 angle α₁₂ and a 1-2 surface 2121 inclined from the upper surface 12 by a 1-2 angle α₂₂ different from the 1-1 angle α₁₂. The 1-2 protrusion 212 may include a bottom surface 2123 in contact with the upper surface 12 and having a certain length l₁₂ and may have a height d₁₂ perpendicular to the bottom surface 2123.

According to an embodiment, a 1-1 angle α₁ of each of the plurality of first protrusions 210 may decrease sequentially in the first direction (+X). Accordingly, a difference between the 1-1 angle α₁ and the 1-2 angle α₂ of each of the plurality of first protrusions 210 may increase sequentially in the first direction (+X). In addition, a height d of each of the plurality of first protrusions 210 may decrease sequentially in the first direction (+X).

For example, the 1-1 protrusion 211 and the 1-2 protrusion 212 may be aligned sequentially in the first direction (+X). The 1-1 angle α₁₂ of the 1-2 protrusion 212 may decrease to be less than the 1-1 angle α₁₁ of the 1-1 protrusion 211. Accordingly, a difference between the 1-1 angle α₁₂ and the 1-2 angle α₂₂ of the 1-2 protrusion 212 may increase to be greater than a difference between the 1-1 angle α₁₁ and the 1-2 angle α₂₁ of the 1-1 protrusion 211. The height d₁₁ of the 1-1 protrusion 211 may decrease to be less than the height d₁₂ of the 1-2 protrusion 212.

Referring to FIG. 5, when the plurality of first protrusions 210 according to an embodiment are aligned in the first direction (+X), for example, when the 1-1 protrusion 211 and the 1-2 protrusion 212 are aligned in the first direction (+X), the force applied to the vapor Wₛ included in the cooling fluid W from surface structures of the 1-1 protrusion 211 and the 1-2 protrusion 212 is calculated by the following Formula 1:

$$F = {\int }_{L}^{R} {A}_{f} ( cos ( {θ}_{1} + {α}_{11} ) - cos ( {θ}_{2} + {α}_{12} ) ) dl . \qquad Formula 1$$

In Formula 1, θ₁ and θ₂ represent a contact angle between the vapor Wₛ and the surfaces of the 1-1 protrusion 211 and the 1-2 protrusion 212, respectively. At represents of surface tension of the vapor Wₛ.

From the result of Formula 1, it may be understood that force F applied to the vapor Wₛ by the surface structures of the 1-1 protrusion 211 and the 1-2 protrusion 212 increases as the difference between a₁ and a₂ increases.

Even when the cooling fluid circulation module 10 hardly inclines, for example, when the upper surface 12 of the cooling fluid circulation module 10 inclines at an angle of 5° or less, the vapor Wₛ may move on the upper surface 12 in the first direction (+X) without any external force.

Each of the plurality of second protrusions 220 according to an embodiment may have an asymmetrical triangular cross-section taken along a plane (XZ plane) perpendicular to the lower surface 11. For example, as illustrated in FIG. 4, the plurality of second protrusions 220 may include a 2-1 protrusion 221 and a 2-2 protrusion 222 aligned in the first direction (+X). Although FIG. 4 illustrates only two protrusions, the disclosure is not limited thereto. The plurality of second protrusions 220 may include, according to the length of the first cooling channel 110, more than two protrusions aligned in order in the first direction (+X). Hereinafter, each of the plurality of second protrusions 220 is described focusing on the 2-1 protrusion 221 and the 2-2 protrusion 222 for convenience sake.

The 2-1 protrusion 221 may include a 2-1 surface 2210 inclined from the lower surface 11 by a 2-1 angle α₃₁ and a 2-2 surface 2211 inclined from the lower surface 11 by a 2-2 angle α₄₁ different from the 2-1 angle α₃₁. The 2-1 protrusion 221 may include a bottom surface 2213 in contact with the lower surface 11 and having a certain length l₂₁ and may have a height d₂₁ perpendicular to the bottom surface 2213. The 2-2 protrusion 222 may include a 2-1 surface 2220 inclined from the lower surface 11 by a 2-1 angle α₃₂ and a 2-2 surface 2221 inclined from the lower surface 11 by a 2-2 angle α₄₂ different from the 2-1 angle α₃₂. The 2-2 protrusion 222 may include a bottom surface 2223 in contact with the lower surface 11 and having a certain length l₂₂ and may have a height d₂₂ perpendicular to the bottom surface 2223.

According to an embodiment, a 2-1 angle as of each of the plurality of second protrusions 220 may decrease sequentially in the first direction (+X). Accordingly, a difference between the 2-1 angle α₃ and the 2-2 angle α₄ of each of the plurality of second protrusions 220 may increase sequentially in the first direction (+X). In addition, a height d of each of the plurality of second protrusions 220 may decrease sequentially in the first direction (+X).

As described above in relation to the plurality of first protrusions 210, it may be understood that the force F applied to the vapor Wₛ by the surface structures of the 2-1 protrusion 221 and the 2-2 protrusion 222 increases as the difference between the 2-1 angle α₃ and the 2-2 angle α₄ increases.

Accordingly, even when the cooling fluid circulation module 10 hardly inclines, for example, when the lower surface 11 of the cooling fluid circulation module 10 inclines at an angle of 5° or less, the vapor Wₛ may move on the lower surface 11 in the first direction (+X) without any external force.

As described above, as the vapor Wₛ moves in the first direction (+X) and a plurality of vapors Wₛ combine, the size of the vapor Wₛ may increase gradually. In this regard, constant momentum may be provided to the vapor Wₛ arranged in the first cooling channel 110 in the first direction (+X), and the vapor Wₛ in the first cooling channel 110 may move in the first direction (+X). Therefore, a coolant supply means such as a high-capacity pump, etc. for moving the vapor Wₛ along the first cooling channel 110 in the first direction (+X) may be omitted. This may allow miniaturization of the cooling fluid circulation module 10 and reduction in power consumption. Moreover, as the plurality of first protrusions 210 and the plurality of second protrusions 220 increase a heat transfer area of the heat transfer surface, heat exchange with a heat source, for example, the heating portion 20 may be facilitated.

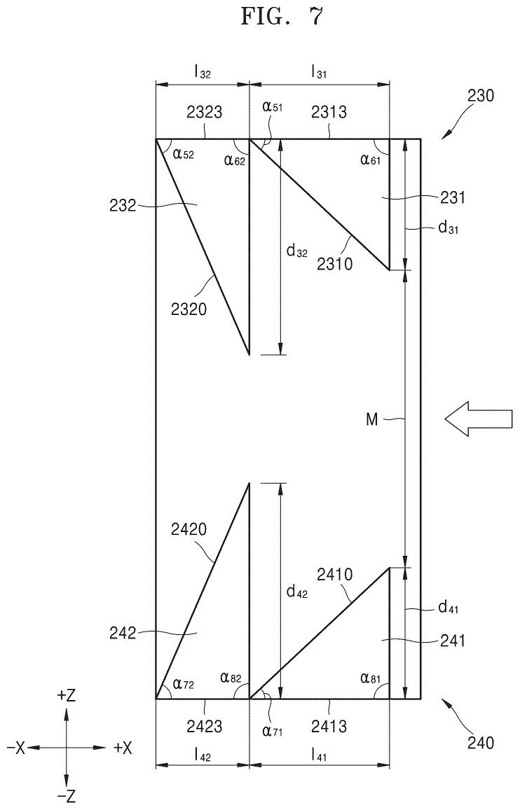

FIG. 6 is a schematic cross-sectional view of an electronic device according to an embodiment. FIG. 7 is a schematic diagram of a plurality of third protrusions, a plurality of fourth protrusions, and a second cooling channel according to an embodiment.

Referring to FIGS. 2, 6 and 7, to move along the second cooling channel 120 the cooling fluid W including the vapor Wₛ and the liquid cooling fluid Wₜ moved from the first cooling channel 110 to the second cooling channel 120, a plurality of third protrusions 230 may be arranged along a plane (XY) on the upper surface 12 on which the second cooling channel 120 is arranged, and a plurality of fourth protrusions 240 may be arranged along a plane (XY) on the lower surface 11 on which the second cooling channel 120 is arranged.

Each of the plurality of third protrusions 230 according to an embodiment may have an asymmetrical triangular cross-section taken along a plane (XZ plane) perpendicular to the upper surface 12. For example, as illustrated in FIG. 7, the plurality of third protrusions 230 may include a 3-1 protrusion 231 and a 3-2 protrusion 232 aligned in the second direction (−X). Although FIG. 7 illustrates only two protrusions, the disclosure is not limited thereto. The plurality of third protrusions 230 may include, according to the length of the second cooling channel 120, two or more protrusions aligned in order in the second direction (−X). Hereinafter, each of the plurality of third protrusions 230 is described focusing on the 3-1 protrusion 231 and the 3-2 protrusion 232 for convenience sake.

The 3-1 protrusion 231 may include a 3-1 surface 2310 inclined from the upper surface 12 by a 3-1 angle α₅₁ and a 3-2 surface 2311 inclined from the upper surface 12 by a 3-2 angle α₆₁ different from the 3-1 angle α₅₁. The 3-1 protrusion 231 may include a bottom surface 2313 in contact with the upper surface 12 and having a certain length l₃₁ and may have a height d₃₁ perpendicular to the bottom surface 2313. The 3-2 protrusion 232 may include a 3-1 surface 2320 inclined from the upper surface 12 by a 3-1 angle α₅₂ and a 3-2 surface 2321 inclined from the upper surface 12 by a 3-2 angle α₆₂ different from the 3-1 angle α₅₂. The 3-2 protrusion 232 may include a bottom surface 2323 in contact with the upper surface 12 and having a certain length l₃₂ and may have a height d₃₂ perpendicular to the bottom surface 2323.

According to an embodiment, a 3-1 angle α₅ of each of the plurality of third protrusions 230 may increase sequentially in the second direction (−X). Accordingly, a difference between the 3-1 angle α₅ and the 3-2 angle α₆ of each of the plurality of third protrusions 230 may decrease sequentially in the second direction (—X). In addition, a height d of each of the plurality of third protrusions 230 may increase sequentially in the second direction (−X).

For example, the 3-1 protrusion 231 and the 3-2 protrusion 232 may be aligned sequentially in the second direction (−X). In this regard, the 3-1 angle α₅₂ from the upper surface 12 of the 3-2 protrusion 232 may increase to be greater than the 3-1 angle α₅₁ from the upper surface 12 of the 3-1 protrusion 231. Accordingly, a difference between the 3-1 angle α₅₂ and the 3-2 angle α₆₂ of the 3-2 protrusion 232 may decrease to be less than a difference between the 3-1 angle α₅₁ and the 3-2 angle α₆₁ of the 3-1 protrusion 231. The height d₃₂ of the 3-2 protrusion 232 may increase to be greater than the height d₃₁ of the 3-1 protrusion 231.

Each of the plurality of fourth protrusions 240 according to an embodiment may have an asymmetrical triangular cross-section taken along a plane (XZ plane) perpendicular to the lower surface 11. For example, as illustrated in FIG. 7, the plurality of fourth protrusions 240 may include a 4-1 protrusion 241 and a 4-2 protrusion 242 aligned in the second direction (−X). Although FIG. 7 illustrates only two protrusions, the disclosure is not limited thereto.

The 4-1 protrusion 241 may include a 4-1 surface 2410 inclined from the lower surface 11 by a 4-1 angle α₇₁ and a 4-2 surface 2411 inclined from the lower surface 11 by a 4-2 angle α₈₁ different from the 4-1 angle α₇₁. The 4-1 protrusion 241 may include a bottom surface 2413 in contact with the lower surface 11 and having a certain length l₄₁ and may have a height d₄₁ perpendicular to the bottom surface 2413. The 4-2 protrusion 242 may include a 4-1 surface 2420 inclined from the lower surface 11 by a 4-1 angle α₇₂ and a 4-2 surface 2421 inclined from the lower surface 11 by a 4-2 angle α₈₂ different from the 4-1 angle α₇₂. The 4-2 protrusion 242 may include a bottom surface 2423 in contact with the lower surface 11 and having a certain length l₄₂ and may have a height d₄₂ perpendicular to the bottom surface 2423.

According to an embodiment, a 4-1 angle α₇ of each of the plurality of fourth protrusions 240 may increase sequentially in the second direction (−X). Accordingly, a difference between the 4-1 angle α₇ and the 4-2 angle as of each of the plurality of fourth protrusions 240 may decrease sequentially in the second direction (—X). In addition, a height d of each of the plurality of fourth protrusions 240 may increase sequentially in the second direction (−X).

For example, the 4-1 protrusion 241 and the 4-2 protrusion 242 may be aligned sequentially in the second direction (−X). In this regard, the 4-1 angle α₇₂ from the lower surface 11 of the 4-2 protrusion 242 may increase to be greater than the 4-1 angle α₇₁ from the lower surface 11 of the 4-1 protrusion 241. Accordingly, a difference between the 4-1 angle α₇₂ and the 4-2 angle α₈₂ of the 4-2 protrusion 242 may decrease to be less than a difference between the 4-1 angle α₇₁ and the 4-2 angle α₈₁ of the 4-1 protrusion 241. The height d₄₂ of the 4-2 protrusion 242 may increase to be greater than the height d₄₁ of the 4-1 protrusion 241.

As the cooling fluid W including the vapor Wₛ moves in the second cooling channel 120 in the second direction (−X) according to an embodiment, heat included in the cooling fluid W may be released by the cooling portion 30. As the vapors Wₛ included in the cooling fluid W combine, the size of the vapor Wₛ may gradually decrease and then dissipate at the final step. In this regard, as the height (d₃, d₄) of each of the plurality of third protrusions 230 and the plurality of fourth protrusions 240 increases in the second direction (−X), the distance M between the plurality of third protrusions 230 and the plurality of fourth protrusions 240 may gradually decrease in the second direction (−X). A difference between a 3-1 angle W₅ and a 3-2 angle W₆ of each of the plurality of third protrusions 230 may decrease sequentially in the second direction (−X), and a difference between a 4-1 angle W₇ and a 4-2 angle We of each of the plurality of third protrusions 230 may decrease sequentially in the second direction (−X). Accordingly, the second cooling channel 120 may have a gradient structure in which a cross-sectional area thereof decreases in the second direction (−X).

As the cross-sectional area of the second cooling channel 120 decreases sequentially in the second direction (−X), there may be a pressure difference between both ends of the second cooling channel 120. Thus, constant momentum may be provided to the cooling fluid W accommodated in the second cooling channel 120 in the second direction (−X), and the cooling fluid W in the second cooling channel 120 may move in the second direction (−X). Therefore, a coolant supply means such as a high-capacity pump, etc. for moving the cooling fluid W along the second cooling channel 120 in the second direction (−X) may be omitted. This may allow miniaturization of the cooling fluid circulation module 10 and reduction in power consumption. Moreover, as the plurality of third protrusions 230 and the plurality of fourth protrusions 240 increase a heat transfer area of the heat transfer surface, heat exchange with a heat source, for example, the cooling portion 30 may be facilitated.

Although the cross-sectional area of the second cooling channel 120 is reduced in the second direction (−X) by using the plurality of third protrusions 230, the angle difference thereof, and the height difference in the embodiments described above, the disclosure is not limited thereto. According to another embodiment, an arbitrary shape reducing the cross-sectional area of the second cooling channel 120 in the second direction (−X) may be arranged on at least one of the lower surface 11 and the upper surface 12 of the second cooling channel 120.

The cooling fluid circulation module 10 according to an embodiment may include a material having relatively great thermal conductivity. For example, when the cooling fluid circulation module 10 includes the lower surface 11, the upper surface 12, the middle partition wall 13, the lateral portion 15, and the plurality of first protrusions 210 to the plurality of fourth protrusions 240, the lower surface 11, the upper surface 12, the middle partition wall 13, the lateral portion 15, and the plurality of first protrusions 210 to the plurality of fourth protrusions 240 may include at least one material having relatively great thermal conductivity, for example, at least one of aluminum, copper, and silicon. In this regard, the lower surface 11, the upper surface 12, the middle partition wall 13, the lateral portion 15, and the plurality of first protrusions 210 to the plurality of fourth protrusions 240 of the cooling fluid circulation module 10 may be integrated. However, the disclosure is not limited thereto, and the cooling fluid circulation module 10 may include other materials, and the lower surface 11, the upper surface 12, the middle partition wall 13, the lateral portion 15, and the plurality of first protrusions 210 to the plurality of fourth protrusions 240 may be formed separately and then combined. For example, the plurality of first protrusions 210 to the plurality of fourth protrusions 240 may be formed through a computerized numerical control (CNC) process, etc.

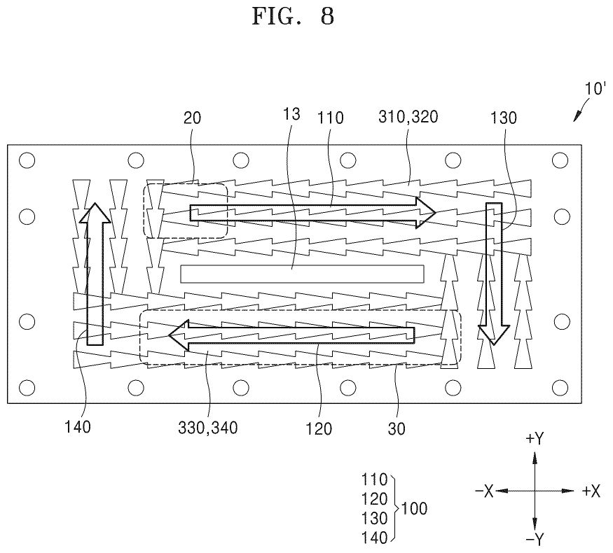

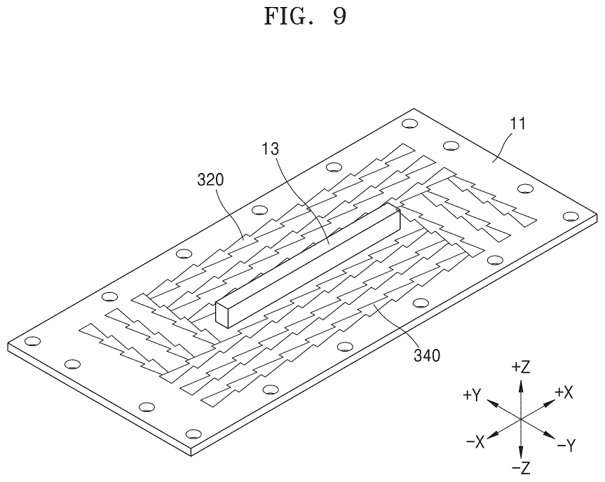

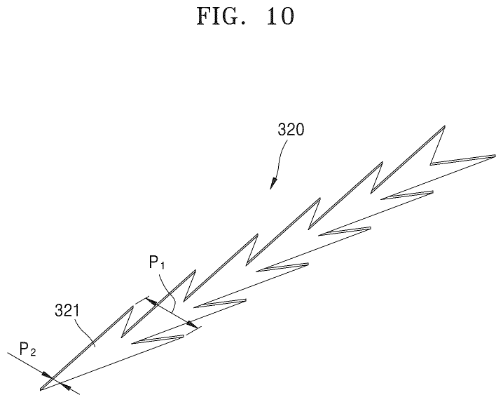

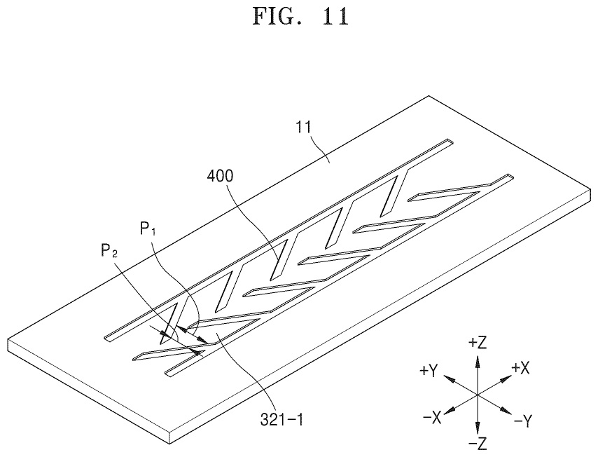

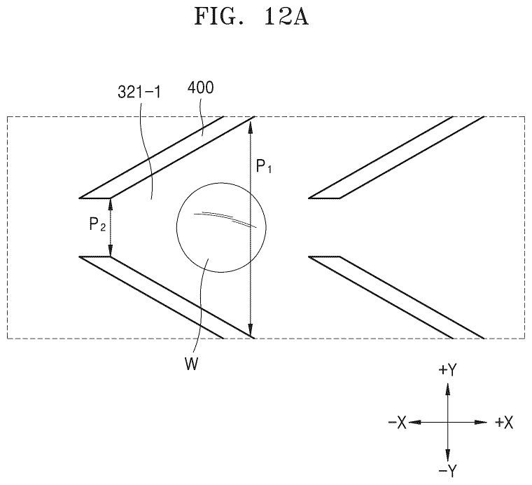

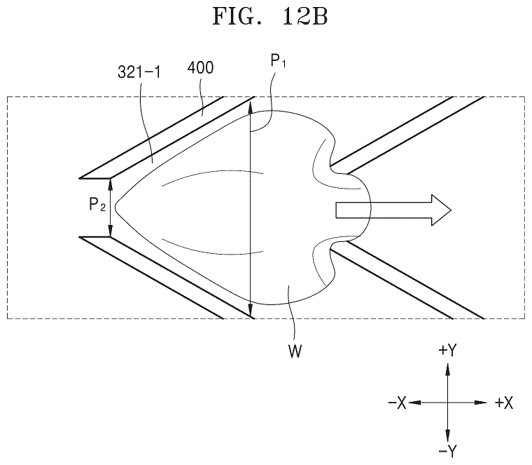

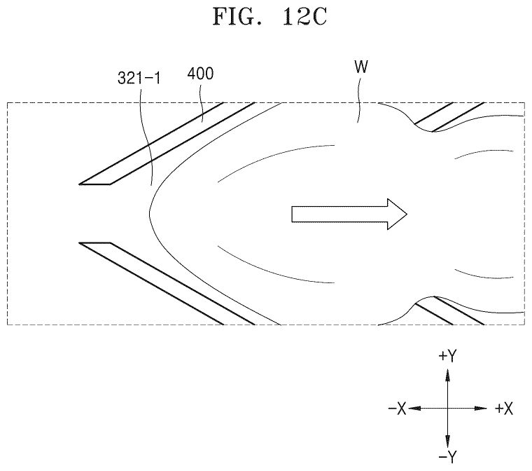

FIG. 8 is a schematic plan view of a cooling fluid circulation module according to an embodiment. FIG. 9 is a schematic perspective view of a lower surface of a cooling fluid circulation module according to an embodiment. FIG. 10 is a schematic diagram of a plurality of second patterns according to an embodiment. FIG. 11 is a schematic diagram of a plurality of second patterns according to an embodiment. FIGS. 12A to 12C are schematic diagrams illustrating a flow of cooling fluid along a plurality of second patterns according to an embodiment.

Referring to FIGS. 8 to 11, a cooling fluid circulation module 10′ may include a lower surface 11 having the plane form and being in contact with a heating portion 20, an upper surface 12 having a plane form and being in contact with a cooling portion 30, and a middle partition wall 13 arranged between the lower surface 11 and the upper surface 12.

The cooling fluid circulation module 10′ according to an embodiment may further include the cooling channel 100 in which the cooling fluid W may move, between the lower surface 11 and the upper surface 12. For example, the cooling channel 100 may include a first cooling channel 110 in contact with the heating portion 20, a second cooling channel 120 in contact with the cooling portion 30, and a third cooling channel 130 and a fourth cooling channel 140 arranged between the first cooling channel 110 and the second cooling channel 120. As components other than a plurality of first patterns 310 and a plurality of second patterns 320 arranged in the first cooling channel 110 and a plurality of third patterns 330 and a plurality of fourth patterns 340 arranged in the second cooling channel 120 are substantially identical to the components described above in relation to FIGS. 1 to 7, redundant descriptions thereon are omitted.

According to an embodiment, to move the stagnant cooling fluid W in the first cooling channel 110 to the second cooling channel 120 where the cooling portion 30 is arranged, the plurality of first patterns 310 may be arranged along a plane (XY) on the upper surface 12 on which the first cooling channel 110 is arranged, and the plurality of second patterns 320 may be arranged along a plane (XY) on the lower surface 11 on which the first cooling channel 110 is arranged.

According to an embodiment, the plurality of first patterns 310 and the plurality of second patterns 320 may include a hydrophobic material. For example, the plurality of first patterns 310 and the plurality of second patterns 320 including a hydrophobic material may be coated on the upper surface 12 and the lower surface 11, respectively. For example, the hydrophobic material included in the plurality of first patterns 310 and the plurality of second patterns 320 may include at least one of perfluoroalkoxy alkane (PFA), polytetrafluoroethylene (PTFE), and polyimide (PI). However, the disclosure is not limited thereto, and the plurality of first patterns 310 and the plurality of second patterns 320 may also include any other hydrophobic material. The lower surface 11 and the upper surface 12 may include at least one hydrophilic material, for example, at least one of aluminum, copper, and silicon. However, the disclosure is not limited thereto, and The lower surface 11 and the upper surface 12 may also include any other hydrophilic material.

In the second direction (−X) opposite to the first direction (+X) in which the cooling fluid W is supposed to move, each of the plurality of second patterns 320 according to an embodiment may have a width P gradually decreasing in the third direction (+Y) perpendicular to the first direction (+X). For example, as illustrated in FIGS. 9 and 10, an end of a second pattern 321 may have a first width P1 in the third direction (+Y), and another end of the second pattern 321 in the second direction (−X) may have a second width P2 in the third direction (+Y). The width of the second pattern 321 may gradually decrease from the first width P1 of one end of the second pattern 321 to the second width P2 of another end of the second pattern 321.

In the embodiment described above, as illustrated in FIGS. 9 and 10, the plurality of second patterns 320 including a hydrophobic material, for example, a partial arrow shape is coated on the lower surface 11 including a hydrophilic material; the disclosure is not limited thereto.

According to an embodiment, as illustrated in FIG. 11, the hydrophobic material may be arranged on the lower surface 11, and a particular shape 400 including a hydrophilic material may be coated on the lower surface 11. Accordingly, the plurality of second patterns 320 including a hydrophobic material in the rest of areas except the particular shape 400 including a hydrophilic material may be formed. For example, an end of a second pattern 321-1 may have the first width P1 in the third direction (+Y), and another end of the second pattern 321-1 in the second direction (—X) may have the second width P2 in the third direction (+Y). The width of the second pattern 321-1 may gradually decrease from the first width P1 of one end of the second pattern 321-1 to the second width P2 of another end of the second pattern 321-1.

As described above, in the second direction (−X) the second pattern (321, 321-1) has the width P gradually decreasing in the third direction (+Y), and accordingly, the contact area between the cooling fluid W and both ends of the second pattern (321, 321-1) may be different from each other. For example, as illustrated in FIG. 12A, when the cooling fluid W has a small size and is not in contact with the second pattern 321-1, the cooling fluid W may not move. When the size of the cooling fluid W increases as illustrated in FIG. 12B, the contact area between the cooling fluid W and both ends of the second pattern 321-1 may be different from each other. In this regard, a contact area between the cooling fluid W and one end of the second pattern 321-1 may be greater than a contact area between the cooling fluid W and the other end of the second pattern 321-1. Accordingly, a momentum difference may be generated due to the difference in the contact area between the cooling fluid W and the second pattern 321-1 including a hydrophobic material, the cooling fluid W may move in the first direction (+X) as illustrated in FIG. 12C.

In the second direction (−X) opposite to the first direction (+X) in which the cooling fluid W is supposed to move, each of the plurality of first patterns 310 according to an embodiment may have a width P gradually decreasing in the third direction (+Y) perpendicular to the first direction (+X). With respect to the plurality of first patterns 310, as features thereof are substantially identical to the features of the plurality second patterns 320 except that the plurality of first patterns 310 are arranged on the upper surface 12, redundant descriptions thereon are omitted.

According to an embodiment, to move the stagnant cooling fluid W in the second cooling channel 120 in the second direction (−X), the plurality of third patterns 330 may be arranged along a plane (XY) on the upper surface 12 on which the second cooling channel 120 is arranged, and the plurality of fourth patterns 340 may be arranged along a plane (XY) on the lower surface 11 on which the second cooling channel 120 is arranged.

According to an embodiment, the plurality of third patterns 330 and the plurality of fourth patterns 340 may include a hydrophobic material. In the first direction (+X) opposite to the second direction (−X) in which the cooling fluid W is supposed to move, each of the plurality of third patterns 330 according to an embodiment may have a width P gradually decreasing in the third direction (+Y) perpendicular to the first direction (+X).

In addition, in the first direction (+X) opposite to the second direction (—X) in which the cooling fluid W is supposed to move, each of the plurality of fourth patterns 340 according to an embodiment may have a width P gradually decreasing in the third direction (+Y) perpendicular to the first direction (+X). With respect to the plurality of third patterns 330 and the plurality of fourth patterns 340, as features thereof are substantially identical to those of the plurality of first patterns 310 and the plurality of second patterns 320 except for the movement direction of the cooling fluid W and the direction in which the width of the pattern decreases, redundant descriptions thereon are omitted.

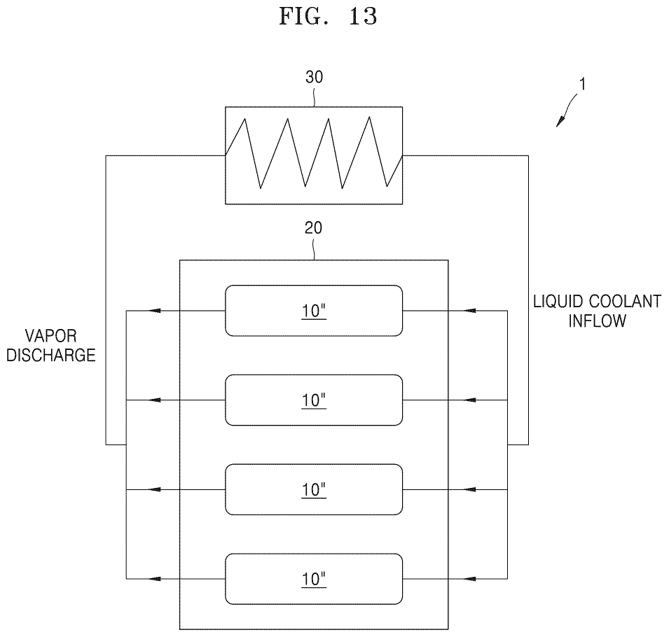

FIG. 13 is a schematic diagram of an electronic device according to an embodiment.

Referring to FIG. 13, the electronic device 1 according to an embodiment may include the heating portion 20, the cooling portion 30, and a cooling fluid circulation module 10″ arranged at the heating portion 20. As the heating portion 20 and the cooling portion 30 according to an embodiment are identical to the heating portion 20 and the cooling portion 30 described above in relation to FIGS. 1 to 7, redundant descriptions thereon are omitted.

There may be plurality of cooling fluid circulation modules 10″ according to an embodiment. According to an embodiment, each of the cooling fluid circulation modules 10″ may be the cooling fluid circulation module (10, 10′) including the first cooling channel (110) capable of moving the cooling fluid W in one direction, for example, in the first direction (+X) from the heating portion 20. As features related to the cooling fluid circulation module (10, 10′) including the first cooling channel (110) are substantially identical to those of the cooling fluid circulation module (10, 10′) described above in relation to FIGS. 1 to 12, redundant descriptions thereon are omitted.

For example, when the heating portion 20 is a large-area device, or when the heat generation amount is relatively great, a plurality of cooling fluid circulation modules 10″ may be arranged at the heating portion 20. Accordingly, a cooling route in which the cooling fluid W moves may be divided by multiple channels. However, the disclosure is not limited thereto, and the plurality of cooling fluid circulation modules 10″ may also be arranged at a large-area device or the cooling portion 30 having a relatively high cooling rate.

According to the disclosure, a cooling fluid circulation module employing a two-phase cooling structure and an electronic device including the cooling fluid circulation module may be provided.

According to the disclosure, a cooling liquid circulation module capable of preventing a decrease in the cooling efficiency due to vapor adsorption in a cooling channel by increasing a movement speed of vapor adsorbed to the cooling channel and an electronic device including the cooling liquid circulation module may be provided.

According to the disclosure, a cooling fluid circulation module having increased efficiency by moving vapor and coolant in one direction without a separate driving device and an electronic device including the cooling fluid circulation module may be provided.

It should be understood that embodiments described herein should be considered in a descriptive sense only and not for purposes of limitation. Descriptions of features or aspects within each embodiment should be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A cooling fluid circulation module comprising:
a first surface having a planar form and contacting a heating portion;
a second surface opposite to the first surface and having a planar form, the second surface being spaced apart from the first surface;
a first cooling channel extending between the first surface and the second surface in a first direction;
a cooling fluid provided in the first cooling channel; and
a plurality of first protrusions arranged along a plane on the second surface on which the first cooling channel extends,
wherein each of the plurality of first protrusions comprises a first surface inclined from the second surface by a first angle and a second surface inclined from the second surface by a second angle that is different than the first angle.

2. The cooling fluid circulation module of claim 1, wherein a difference between the first angle and the second angle of each of the plurality of first protrusions increases sequentially in the first direction, and
wherein a height of each of the plurality of first protrusions decreases sequentially in the first direction.

3. The cooling fluid circulation module of claim 1, further comprising a plurality of second protrusions arranged along a plane on the first surface on which the first cooling channel extends,
wherein each of the plurality of second protrusions comprises a third surface inclined from the first surface by a third angle and a fourth surface inclined from the first surface by a fourth angle that is different than the third angle.

4. The cooling fluid circulation module of claim 3, wherein a difference between the third angle and the fourth angle of each of the plurality of second protrusions increases sequentially in the first direction, and
wherein a height of each of the plurality of second protrusions decreases sequentially in the first direction.

5. The cooling fluid circulation module of claim 1, wherein the cooling fluid comprises at least one of a coolant HFE-7100, a coolant FC-72, a coolant PF-5060, a coolant R-245fa, a coolant R-1233zd, diethyl ether, ethanol, acetone, or distilled water.

6. The cooling fluid circulation module of claim 1, wherein the second surface contacts a cooling portion for cooling the cooling fluid,
wherein the cooling fluid circulation module further comprises:
a second cooling channel extending between the second surface and the first surface in a second direction opposite to the first direction; and
a plurality of third protrusions arranged along a plane on the second surface on which the second cooling channel extends, and
wherein each of the plurality of third protrusions comprises a fifth surface inclined from the second surface by a fifth angle and a sixth surface inclined by the second surface at a sixth angle that is different than the fifth angle.

7. The cooling fluid circulation module of claim 6, wherein a difference between the fifth angle and the sixth angle of each of the plurality of third protrusions decreases sequentially in the second direction, and
wherein a height of each of the plurality of third protrusions increases sequentially in the second direction.

8. The cooling fluid circulation module of claim 6, further comprising a plurality of fourth protrusions arranged along a plane on the first surface on which the second cooling channel is arranged,
wherein each of the plurality of fourth protrusions comprises a seventh surface inclined from the first surface by a seventh angle and an eighth surface inclined from the first surface by an eighth angle that is different than the seventh angle.

9. The cooling fluid circulation module of claim 8, wherein a difference between the seventh angle and the eighth angle of each of the plurality of fourth protrusions decreases sequentially in the second direction, and
wherein a height of each of the plurality of fourth protrusions increases sequentially in the second direction.

10. The cooling fluid circulation module of claim 6, further comprising:
a middle partition wall between the second surface and the first surface, and blocking the first cooling channel and the second cooling channel from each other;
a third cooling channel connecting the first cooling channel to the second cooling channel, and extending in a third direction perpendicular to the first direction; and
a fourth cooling channel connecting the first cooling channel to the second cooling channel, and extending in a fourth direction opposite to the third direction.

11. The cooling fluid circulation module of claim 1, wherein each of the second surface, the first surface, and the plurality of first protrusions comprises at least one of aluminum, copper, or silicon.

12. A cooling fluid circulation module comprising:
a first surface having a planar form and contacting a heating portion;
a second surface having a plane form and opposite to the first surface, the second surface being spaced apart from the first surface;
a first cooling channel between the first surface and the second surface;
a cooling fluid provided in the first cooling channel and moving in a first direction; and
a plurality of first patterns arranged along a plane on the second surface and comprising a hydrophobic material,
wherein each of the plurality of first patterns has a first width in a second direction that is opposite to the first direction, the first width gradually decreasing in a third direction perpendicular to the first direction.

13. The cooling fluid circulation module of claim 12, further comprising a plurality of second patterns arranged along a plane on the first surface and comprising a hydrophobic material,
wherein each of the plurality of second patterns has a second width in the second direction, the second width gradually decreasing in the third direction.

14. The cooling fluid circulation module of claim 13, wherein the hydrophobic material comprises at least one of perfluoroalkoxy alkane (PFA), polytetrafluoroethylene (PTFE), or polyimide (PI).

15. The cooling fluid circulation module of claim 14, wherein each of the second surface and the first surface comprises at least one of aluminum, copper, or silicon.

16. The cooling fluid circulation module of claim 12, wherein the cooling fluid comprises at least one of a coolant HFE-7100, a coolant FC-72, a coolant PF-5060, a coolant R-245fa, a coolant R-1233zd, diethyl ether, ethanol, acetone, or distilled water.

17. The cooling fluid circulation module of claim 12, wherein the second surface contacts a cooling portion,
wherein the cooling fluid circulation module further comprises:
a second cooling channel between the second surface and the first surface, wherein the cooling fluid moves in the second cooling channel in the second direction; and
a plurality of third patterns arranged along a plane on the second surface on which the second cooling channel extends and comprising a hydrophobic material, and
wherein each of the plurality of third patterns has a third width in the first direction, the third width gradually decreasing in the third direction.

18. The cooling fluid circulation module of claim 17, further comprising a plurality of fourth patterns arranged along a plane on the first surface on which the second cooling channel extends, wherein each of the plurality of fourth patterns has a fourth width in the first direction, the fourth width gradually decreasing in the third direction.

19. The cooling fluid circulation module of claim 17, further comprising:
a middle partition wall between the second surface and the first surface, and blocking the first cooling channel and the second cooling channel from each other;
a third cooling channel connecting the first cooling channel to the second cooling channel, and extending in the third direction perpendicular to the first direction; and
a fourth cooling channel connecting the first cooling channel to the second cooling channel, and extending in a fourth direction opposite to the third direction.

20. An electronic device comprising:
a heating portion;
a cooling portion;
a cooling fluid circulation module comprising:
a first surface having a planar form and contacting the heating portion;
a second surface opposite to the first surface and having a planar form, the second surface being spaced apart from the first surface;
a first cooling channel extending between the first surface and the second surface in a first direction;
a cooling fluid provided in the first cooling channel; and
a plurality of first protrusions arranged along a plane on the second surface on which the first cooling channel extends,
wherein each of the plurality of first protrusions comprises a first surface inclined from the second surface by a first angle and a second surface inclined from the second surface by a second angle that is different than the first angle.
